(19) United States
(12) Patent Application Publication
(10) Pub. No.: US 2020/0321159 A1
(43) Pub. Date: Oct. 8, 2020

(54) METHOD AND A MECHANISM CAPABLE OF ANNEALING A GMR SENSOR

(71) Applicants: Genliang Han, Lanzhou (CN); Yuzhe Song, Lanzhou (CN)

(72) Inventors: Genliang Han, Lanzhou (CN); Yuzhe Song, Lanzhou (CN)

(21) Appl. No.: 16/377,245

(22) Filed: Apr. 7, 2019

(51) Int. Cl. H01F 41/34; H01F 10/32; H01L 43/02; H01L 43/12; G01R 33/09

(52) U.S. Cl. CPC H01F 41/34; H01F 10/3268; H01F 10/3254; G01R 33/098; H01L 43/12; G01R 33/093; H01L 43/02

(57) ABSTRACT

A MR structure that comprises ferromagnetic layers separated by a spacer layer is formed on a substrate. One of the ferromagnetic layer is a pinned layer whose magnetic orientation is substantially fixed during operation. An insulating layer is deposited on the MR structure followed by deposition of a metallic layer. The metallic layer is patterned in to heat resistor. The MR structure is annealed by use of the heat resistor and an exte4rnal magnetic field. After annealing, the insulating layer and the heat resistor are removed.

### TECHNICAL FIELD OF THE DISCLOSURE

The technical field of the examples to be disclosed in the following sections is related generally to the art of MR (Magneto-Resistance) sensors; and more particularly to GMR sensors and TMR sensors with integrated annealing mechanisms.

### BACKGROUND OF THE DISCLOSURE

MR sensors such as GMR (Giant Magnetoresistors) sensors and TMR (Tunneling Magnetoresistors) sensors are promising magnetic field sensors and now are widely used in many applications. A typical MR sensor comprises a non-magnetic layer sandwiched between two ferromagnetic layers, as illustrated in FIG. 1. Referring to FIG. 1, MR sensor 10 comprises ferromagnetic layers 12 and 16; and non-magnetic layer 14 between ferromagnetic layers 12 and 16. Ferromagnetic layers 12 and 16 each may comprise NiFe, CoFe and other suitable ferromagnetic materials. Non-magnetic layer 14 comprises Cu or MgO or Al₂O₃ or other suitable non-magnetic materials. Ferromagnetic layer 16 is pinned such that the magnetic orientation of ferromagnetic layer 16 substantially does not move with external magnetic field that is to be detected. As such, ferromagnetic layer 16 is often referred to as “pinned layer.” Ferromagnetic layer 12 is configured such that the magnetic orientation of ferromagnetic layer 12 moves “freely” with external magnetic field that is to be detected. As such, ferromagnetic layer 12 is often referred to as “free layer.”

MR structure 10 can be configured into CIP (current in Plane) and CPP (Current Perpendicular to Plane) forms. In a CIP form, MR structure 10 comprises a non-magnetic layer (14) that is generally Cu. Current flows through the MR structure in parallel to the surfaces of the layers, in a CPP configuration, current flow perpendicular to the layers. The non-magnetic layer (14) is generally an insulating layer, such as Al₂O₃ or MgO layer.

In sensing operations, magnetic orientation Mp of pinned layer (layer 16) is substantially perpendicular to magnetic orientation Mf of free layer (layer 12) so as to obtain a linear response. As illustrated in FIG. 1, Mp is aligned in the Y axis, and Mf is aligned in the X axis in the Cartesian coordinate.

MR sensors are often set up into Wheatstone Bridges to obtain better performance. In various Wheatstone bridges, full Wheatstone bridges, one of which is illustrated in FIG. 2, have the best linearity and signal level. Referring to FIG. 2, four MR resistors R1, R2, R3, and R4 are connected into a Wheatstone bridge. All four MR resistors independently vary with external magnetic signals. The output voltage Vo can be written as equation 1:

$${V}_{o} = {V}_{b} \frac{Δ R}{R} , wherein Vb is the bias voltage ; and \\ {R}_{1} = {R}_{4} = R - Δ R \\ {R}_{2} = {R}_{3} = R + Δ R \qquad Equation 1$$

wherein ΔR is the change of magneto-resistance due to external magnetic signal.

Wheatstone bridge using MR structures (e.g. GMR structure 10 in FIG. 1) can be implemented into various forms depending upon different applications. Regardless of different configurations, MR structures in a full Wheatstone bridge have opposite magnetic orientations, which are illustrated in an exemplary full Wheatstone bridge in FIG. 3. Referring to FIG. 3, MR sensor 18 comprises four MR resistors R1, R2, R3, and R4. The four MR resistors are connected into a Wheatstone bridge. To be operable in full Wheatstone bridge, each one of MR resistors R1, R2, R3, and R4 is capable of changing upon external magnetic field that is to be detected. Moreover, adjacent MR resistors have opposite magnetic orientations Mp of pinned layers. For example, R1 and R2 have opposite magnetic orientations Mp of pinned layers. R3 and R4 have opposite magnetic orientations Mp of pinned layers. R1 and R3 have the same magnetic orientation Mp of their pinned layers; and so does the pair of R2 and R4.

In order to align magnetic orientations MP of the pinned layers in adjacent MR resistors (e.g. R1 and R2; R3 and R4), localized laser heating technology has been developed in current technologies. MR sensor 18 is placed in an external magnetic field Hb. MR structures are divided into two groups with each group having the same magnetic orientation Mp; and different groups having opposite magnetic orientation Mp. By selecting a first group (e.g. R1 and R3), a beam of laser is directed to each MR structure in this selected group and heats the temperature of the MR structure above its blocking temperature so as to align the magnetic orientation Mp of the MR structure along the external magnetic field Hb. This process continuous for all MR structures in the selected group. After aligning the MR structures in the first selected group (e.g. R1 and R3), the MR sensor (18) is rotated 180° degrees so as to inverse the direction of external magnetic field Hb. Alternatively, the external magnetic field Hb can be reversed without rotating MR sensor 18. After reversing the external magnetic field Hb, laser beam is directed to each one of the MR structures of the second MR group (e.g. R2 and R4); and the annealing process is performed in the same way as for selected group one (e.g. R1 and R3).

There is another process in forming the full Wheatstone bridge MR sensor 18 by using multiple photolithography processes. After forming the thin film stacks of MR structures, MR structures (e.g. R1 and R3) of the same magnetic orientation Mp are fabricated by photolithography. The fabricated MR structures R1 and R3 are then covered by magnetic shielding materials. MR structures (e.g. R2 and R4) of the second group are deposited and patterned with the external magnetic field Hb reversed. Because the previously formed MR structures R1 and R3 are covered by magnetic shielding materials, R1 and R3 are substantially not affected by the reversed magnetic field Hb during fabrication of MR structures R2 and R4 in the second process.

It can be seen that the localized laser heating process and multi-photolithography lack efficiency and accuracy, which may not be applicable especially for industrial production.

Therefore, what is desired is a mechanism and/or a method of forming MR sensors having full Wheatstone bridges using MR structures.

### SUMMARY OF THE DISCLOSURE

In view of the foregoing, a method of forming a MR structure is disclosed herein, the method comprises: forming a MR structure, comprising: forming the MR structure on a substrate, wherein the MR structure comprises a pinned layer and a free layer that is spaced between a non-magnetic layer, wherein the pinned layer and the free layer are ferromagnetic layers; depositing an insulating layer on the MR structure; and forming a heat resister on the insulating layer, further comprising: depositing a metallic layer on the insulating layer; and patterning the metallic layer into the heat resistor; adjusting the magnetic orientation of the pinned layer, comprising: applying a magnetic field; feeding current through the heat resistor so that the temperature of the MR structure is equal to or higher than the blocking temperature; removing the current; and removing the insulating layer and the heat resistor.

In another example, a method of forming a first and second MR structures, wherein each MR structure comprises a pinned layer, the method comprises: forming the first and second MR structures that comprises: depositing a pinned layer, a non-magnetic spacing layer, and a free layer on a substrate, wherein the pinned layer and the free layer are ferromagnetic layers; depositing an insulating layer; and patterning the insulating layer in to a first and second heat resistors, wherein the first and second heat resistors are respectively on the insulating layers of the the first and second MR structures; annealing the first and second MR structures, comprising: providing a magnetic field along a first magnetic direction; raising the temperature of the pinned layer of the first MR structure to or above its blocking temperature by feeding current through the first heat resistance; cooling down the first MR structure by removing the current from the first resistance; realigning the magnetic field along a second magnetic direction; raising the temperature of the pinned layer of the second MR structure to or above its blocking temperature by feeding current through the second heat resistance; and cooling down the second MR structure by removing the current from the second resistance; and removing the insulating layer and the first and second heat resistors.

### BRIEF DESCRIPTION OF DRAWINGS

FIG. 1 diagrammatically illustrates a MR structure having a non-magnetic thin film layer sandwiched between ferromagnetic thin layers;

FIG. 2 is a diagram of a full Wheatstone bridge of MR resistors;

FIG. 3 diagrammatically illustrates a full Wheatstone bridge of MR resistors;

FIG. 4 diagrammatically illustrates a wafer having multiple dies, wherein each die comprises a Wheatstone bridge of MR resistors;

FIG. 5 diagrammatically illustrates a cross section of an exemplary MR structure and a heating mechanism formed on top of the MR structure during an exemplary annealing process;

FIG. 6 diagrammatically illustrates a cross-section of two adjacent MR structures during an exemplary fabrication process so as to obtain different (e.g. opposite) magnetic orientations of the pinned layers in the different MR structures;

FIG. 7 illustrates a diagram of a layout of heating resistors used in an exemplary annealing process for MR resistors; and

FIG. 8 is a flow chart showing the steps executed in performing an exemplary annealing process.

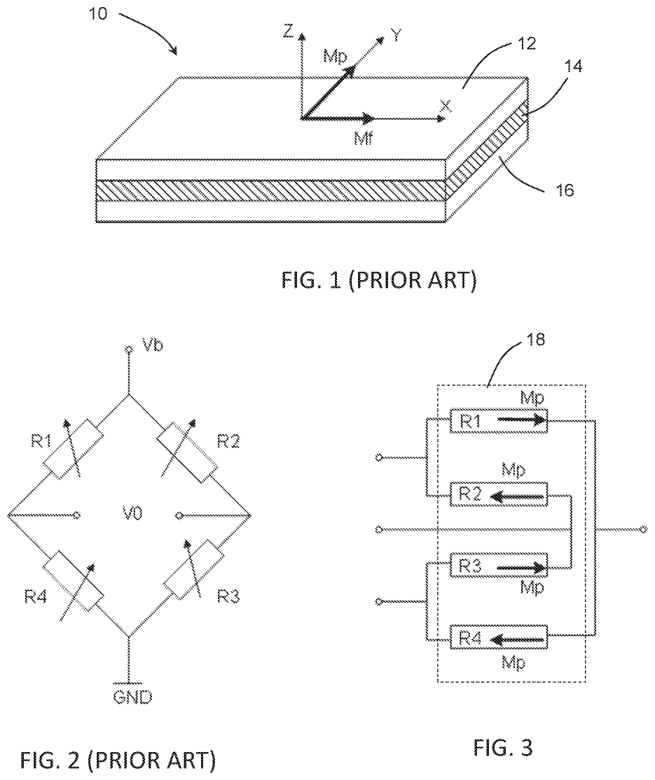

### DETAILED DESCRIPTION OF SELECTED EXAMPLES

Disclosed herein include a method and a mechanism capable of annealing MR resistors so that the pinned magnetic layers of different MR resistors have different magnetic orientations. In particular, the pinned layers of neighboring MR resistors have substantially opposite magnetic orientations. In one example, the annealed MR resistors can be configured into a full Wheatstone bridge. The MR can be any applicable magnetoresistors, such as GMR (Giant Magnetoresistor) and TMR (Tunneling Magnetoresistor).

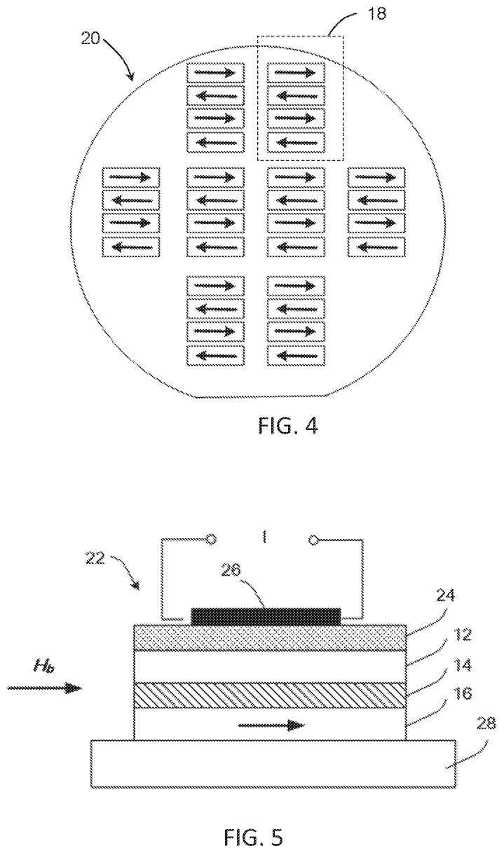

As discussed above with reference to FIG. 3, a MR sensor having a full Wheatstone bridge generally comprises four MR structures, wherein each MR structure is a magnetoresistor, such as a GMR or a TMR resistor. Each magnetoresistor of the full Wheatstone bridge varies with target magnetic field (the magnetic field to be detected or measured). The adjacent magnetoresistors have substantially opposite magnetic orientations Mₚ. Often times, the MR sensors are fabricated in to dies of a wafer, as schematically illustrated in FIG. 4. Referring to FIG. 4, wafer 20 comprises multiple dies such as die 18. The dies comprise MR sensors such as the MR sensor in die 18 and the MR sensor in die 18 is discussed above with reference to FIG. 3. It is noted that adjacent MR structures in each MR full Wheatstone bridge die have substantially opposite magnetic orientations Mₚ. In order to efficiently accomplish such differently orientated magnetic orientations in MR sensors, an annealing method and a mechanism are proposed herein.

Adjustment of magnetic orientation Mₚ of a MR structure is generally accomplished through a so named “annealing” process. The MR structure is heated to a temperature to or above its blocking temperature T_{b}. In the presence of an external magnetic field H_{b}, the magnetic orientation Mₚ is aligned to the direction of the external magnetic field H_{b}. After such alignment, the MR structure can be cooled down such that aligned magnetic orientation is substantially fixed.

For MR structures with different magnetic orientations Mₚ in a sensor or a die on a wafer, it is very hard to apply magnetic fields of different directions independently to individual MR structures. Heating MR structures individually to or above their blocking temperatures, whereas a magnetic field is applied to all MR structures can be an efficient way to accomplish the annealing process. For individually heating MR structures, heating resistors can be provided to the MR resistors so that the MR structures can be individually heated or, can be heated in desired groups. By heating the MR to their blocking temperatures T_{b} in the presence of magnetic field H_{b}, the magnetic orientation can thus be adjusted. Because the MR resistors can be heated independently or in desired groups, the MR resistors can be configured to obtain different magnetic orientations of the pinned layers in different MR structures.

As an example, FIG. 5 schematically illustrates a method and a mechanism capable of annealing MR structures to obtain pinned layers of different magnetic orientations. Referring to FIG. 5, MR structure 22 comprises non-magnetic layer 14 that is laminated between ferromagnetic layers 12 and 16. Insulating layer 24 is deposited on top of the MR structure (22), for example, on top of ferromagnetic layer 12. Heating resistor 26 is formed on insulating layer 24. For establishing the magnetic orientation of pinned layer 16, biasing magnetic field H_{b} is applied. In the presence of bias magnetic field H_{b}, the temperature ferromagnetic layer 16 is raised equal to or above its blocking temperature T_{b}. This is achieved by feeding current I through heat resistor 26. The heat resistor (26) generates Joule heat, which raises the temperature of ferromagnetic layer 16 to or above its blocking temperature T_{b}. After the magnetic orientation of ferromagnetic layer 16 is settled, the current through heat resistor 26 is removed; and ferromagnetic layer 16 is cooled down. The bias magnetic field H_{b} can be removed. Heating resistor 26 can be removed afterwards to obtain MR sensor. Insulating layer 24 can be removed upon necessary. It is noted that the heating resistor (26) and insulating layer (24) can be removed using any suitable ways depending upon the material and the formation process of the heating resistor and insulating layer. For example, the heat resistor (26) can be removed from a lift-off process. The heat resistor can also be removed by an etching process that is suitable for etching metallic materials. The insulating layer (24) can be removed by any suitable process for etching insulating materials, such as a gaseous etching process, e.g. using HF etchant.

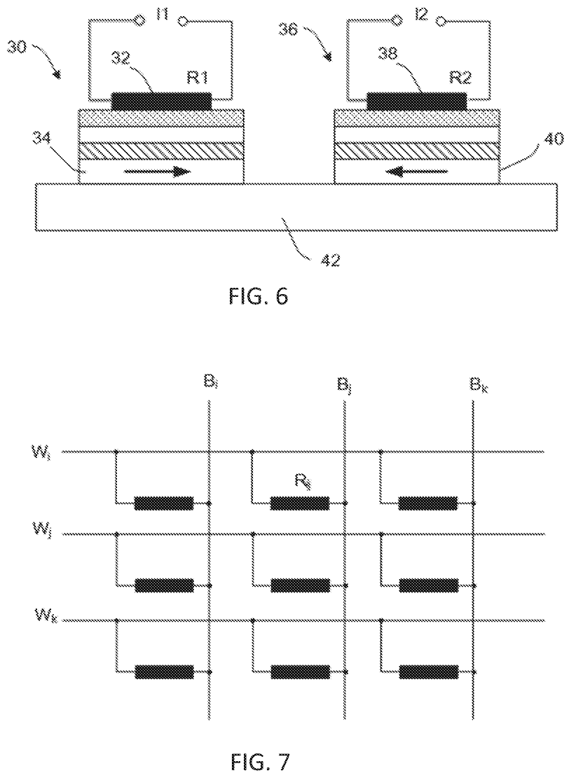

The above process can be used to annealing individual MR structures independently so as to obtain different magnetic orientations, an example of which is illustrated in FIG. 6. Referring to FIG. 6, MR structures 30 and 36 are neighboring MR structures. MR structures 30 has pinned layer 34 and heat resistor 32. MR structure 36 has ferromagnetic layer 40 and heat resistor 38. The different magnetic orientations of layers 34 and 40 can be obtained by multiple annealing processes with the aid of heat resistors 32 and 38. In a first annealing process, MR structures 30 and 36 can be disposed in an external magnetic field H_{b} that is aligned toward the right direction (e.g. in the same direction as the direction of layer 34 of MR structure 30). Current I₁ is fed into heat resistor 32 so as to raise the temperature of MR structure 30 to or above its blocking temperature T_{b}. In the presence of the bias magnetic field H_{b} and with the raised temperature, the magnetic orientation of pinned layer 34 is aligned to H_{b} as schematically illustrated in FIG. 6. MR structure 30 can then be cooled down to a temperature below the blocking temperature T_{b} by removing the current. In order to obtain a different (e.g. opposite) magnetic orientation (e.g. toward left as illustrated in FIG. 6) of layer 40 in MR structure 36, the bias magnetic field H_{b} is revised (e.g. by rotating the bias magnetic field 180 degrees, or by rotating the MR structures 30 and 36 180 degrees relative to the bias magnetic field H_{b}). After aligning layer 40 to the bias magnetic field H_{b} properly, current is fed into heat resister 38 so as to elevate layer 40 to a temperature equal to or above the blocking temperature T_{b}. With the elevated temperature and in the presence of the bias magnetic field H_{b}, the magnetic orientation of layer 40 is aligned to the bias magnetic field H_{b} as illustrated in FIG. 6. As such, layers 34 and 40 of MR structures 30 and 36 have different (e.g. opposite) magnetic directions.

The annealing process can be performed on a wafer before cutting the wafers into individual dies. The heating resistors of the MR structures can be connected into multiple groups so as to enable annealing of different groups of MR structures. In another example, the heating resistors of MR structures can be connected through word lines and bit lines, an example of which is illustrated in FIG. 7.

Referring to FIG. 7, multiple heating resistors such as Rᵢⱼ are connected to word lines (e.g. word lines Wᵢ, Wⱼ, Wₖ) at one ends; and to bit lines (e.g. bit lines Bᵢ, Bⱼ, and Bₖ) at the other ends. Each heat resistor can be individually addressed by connected word line and bit line. For example, heat resistor Rᵢⱼ can be addressed by word line Wᵢ and bit line Bⱼ. Heat resistor Rᵢⱼ can be heated by fed current through word line Wᵢ and bit line Bⱼ. It is noted that FIG. 7 is for demonstration purpose only, and should not be interpreted as a limitation. For example, many heat resistors can be connected and activated through word lines and bit lines. For another example, a group of heat resistors (e.g. heat resistors connected by the same word line or same bit line) can be addressed and activated at the same time so as to be annealed through one annealing process, wherein the MRs of such group have substantially the same magnetic orientation. Another or other groups of MRs can be addressed and annealed through different processed at different time by aligning the MRs along different bias magnetic field directions.

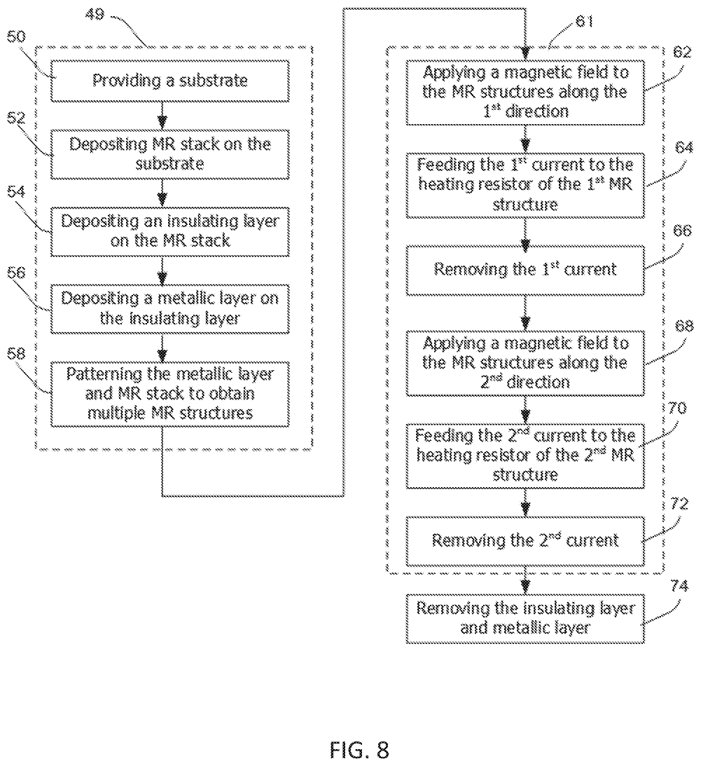

FIG. 8 is a flow chart showing the steps executed in an exemplary embodiment of this invention. Referring to FIG. 8, MR structures (e.g. MR structures 30 and 36 in FIG. 6) is fabricated at step 49, wherein the MR structures comprise heating resistors. The heating resistors are used to anneal MR structures individually so as to obtain different magnetic orientations in different MR structures as necessary (step 61). The heating resistors are removed afterwards through step 74. In a particular example, fabrication of MR structures (step 49) starts from a step of providing a substrate (step 50). MR stack is deposited on the substrate (step 52). The MR stack can be AMR stack. GMR stack, TMR stack or other magnetoresistor stacks. For example, the GMR stack can be a top pinned spin-valve stack, or a bottom pinned spin-valve stack. The details of top pinned spin-valve stack and bottom pinned spin-valve stack are not described herein for simplicity because they are already widely disclosed in the prior art.

After the deposition of MR stack, an insulating layer is deposited on the MR stack (step 54) followed by a step (56) of depositing a metallic layer on the insulating layer. The insulating layer can be of any suitable materials capable of electrically insulating the metallic layer from the MR stack, such as SiOₓ, Al₂O₃. The MR stack, as well as the top metallic layer, is patterned into multiple MR structures (step 58). Each patterned MR structure has a heating resistor from the patterned metallic layer. With the heating resistors patterned from the metallic layer, the MR structures are annealed at step 61. The annealing step (61) starts from step 62, wherein a magnetic field is applied. The magnetic field is aligned to the MR structures along the 1^{st} direction. The 1^{st} current is fed into the heating resistor of the 1^{st} MR structure (step 62). The current flowing through the heating resistor generates Joule heat so as to raise the temperature of the 1^{st} MR structure to or above its blocking temperature T_{b}. At the raised temperature and in the presence of magnetic field, the magnetic orientation of the 1^{st} MR structure is set. In particular, the magnetic orientation of the pinned layer in the 1^{st} MR structure is settled (e.g. to the 1^{st} direction of the applied magnetic field). After setting the magnetic orientation of the 1^{st} MR structure, the 1^{st} current is removed (step 66) from the heat resistor of the 1^{st} MR structure so as to cool down the 1^{st} MR structure below its blocking temperature T_{b}. After annealing the 1^{st} MR structure, the 2^{nd} MR structure is annealed by starting from step 68.

At step 68, the magnetic field is aligned to the 2^{nd} direction relative to the 1^{st} direction. This can be achieved by rotating the magnetic field relative to the 1^{st} direction, or can be achieved by rotating the MR structure relative to the magnetic field. In a particular example, the 2^{nd} direction of the magnetic field is 180° degrees relative to the 1^{st} direction. The MR structures are rotated 180° degrees and the magnetic field is still aligned to the 1^{st} direction. A 2^{nd} current is fed into the heat resistor of the 2^{nd} MR structure to raise the temperature of the 2^{nd} MR structure to or above its blocking temperature T_{b}. In the presence of the magnetic field and raised temperature, the 2^{nd} MR structure is annealed. The magnetic orientation of the pinned layer of the 2^{nd} MR structure is settled to the 2^{nd} direction (e.g. 180° degrees relative to the 1^{st} magnetic direction). The 2^{nd} current is removed after annealing the 2^{nd} MR structure (step 72). The magnetic field may or may not be removed.

After annealing the 1^{st} and 2^{nd} MR structures, or other MR structures if necessary, the insulating layer (e,g. layer 24 in FIG. 5) and heat resistors (e,g. 26 in FIG. 5) are removed (step 74). The MR structures are exposed and annealed, wherein a 1^{st} MR structure has a pinned layer along the 1^{st} direction and the 2^{nd} MR structure has a pinned layer along the 2^{nd} direction.

It will be appreciated by those of skilled in the art that a new and useful method of processing MR structures so as to obtain different magnetic orientations of the pinned layers in MT structures is disclosed herein. In view of the many possible embodiments, however, it should be recognized that the embodiments described herein with respect to the drawing figures are meant to be illustrative only and should not be taken as limiting the scope of what is claimed. Those of skill in the art will recognize that the illustrated embodiments can be modified in arrangement and detail. Therefore, the devices and methods as described herein contemplate all such embodiments as may come within the scope of the following claims and equivalents thereof. In the claims, only elements denoted by the words “means for” are intended to be interpreted as means plus function claims under 35 U.S.C. § 112, the sixth paragraph.

1. A method, comprising the steps of:
forming a MR structure, comprising:
forming the MR structure on a substrate, wherein the MR structure comprises a pinned layer and a free layer that is spaced between a non-magnetic layer, wherein the pinned layer and the free layer are ferromagnetic layers;
depositing an insulating layer on the MR structure; and
forming a heat resister on the insulating layer, further comprising:
depositing a metallic layer on the insulating layer; and
patterning the metallic layer into the heat resistor;
adjusting the magnetic orientation of the pinned layer, comprising:
applying a magnetic field;
feeding current through the heat resistor so that the temperature of the MR structure is equal to or higher than the blocking temperature;
removing the current; and
removing the insulating layer and the heat resistor.

2. The method of claim 1, wherein the MR structure is a GMR structure that comprises two ferromagnetic layers separated by a metallic layer that is copper.

3. The method of claim 2, wherein the MR structure is a TMR structure that comprises two ferromagnetic layers separated by an oxide layer.

4. The method of claim 3, wherein the oxide layer is Al₂O₃.

5. The method of claim 3, wherein the oxide layer is MgO.

6. The method of claim 1, wherein the insulating layer comprises SiOₓ.

7. The method of claim 1, wherein the insulating layer comprises SiO₂.

8. The method of claim 1, wherein the insulating layer comprises SiN.

9-15. (canceled)
